(19) United States
(12) Patent Application Publication
(10) Pub. No.: US 2021/0036170 A1
(43) Pub. Date: Feb. 4, 2021

(54) PHOTODIODE WITH ANTIREFLECTIVE AND HIGH CONDUCTIVE METAL-SEMICONDUCTOR STRUCTURE, METHOD FOR MANUFACTURING THE SAME, AND SOLAR CELL COMPRISING THE SAME

(71) Applicant: UIF (University Industry Foundation), Yonsei University, Seoul (KR)

(72) Inventors: Jungwoo OH, Incheon (KR); Kyunghwan KIM, Incheon (KR); Bugeun KI, Incheon (KR); Keorock CHOI, Incheon (KR)

(21) Appl. No.: 16/945,300

(22) Filed: Jul. 31, 2020

(30) Foreign Application Priority Data
Aug. 1, 2019 (KR) 10-2019-0093811
Jul. 31, 2020 (KR) 10-2020--0095741

(51) Int. Cl. H01L 31/0224; H01L 31/18; H01L 31/0352

(52) U.S. Cl. CPC H01L 31/022425; H01L 31/184; H01L 31/068; H01L 31/035227; H01L 31/1804

(57) ABSTRACT

The present disclosure provides a photodiode which maintains a photodiode characteristic even after the metal-assisted chemical etching and uses a metal-semiconductor structure having low reflectance and high conductance, a manufacturing method thereof, and a solar cell using the same. The photodiode of the present disclosure includes a semiconductor substrate with a low reflective and high conductive surface which has a selectively etched electrode formation area and a high conductive electrode formed by placing a metal catalyst used for a metal-assisted chemical etching process for forming an antireflection semiconductor substrate in an etching area of the antireflection semiconductor substrate.

### PRIORITY

This application claims the benefit under of a Korean patent application filed in the Korean Intellectual Property Office on Aug. 1, 2019 and assigned Serial No. 10-2019-0093811, and Jul. 31, 2020 and assigned Serial No. 10-2020-0095741, the entire disclosure of which is hereby incorporated by reference.

### TECHNICAL FIELD

The present disclosure relates to an optical device such as a photodiode and a manufacturing method of the same, and more particularly, to a photodiode with a nanostructure, a method for manufacturing a photodiode, and a solar cell including the same.

### BACKGROUND ART

A metal-assisted chemical etching (MacEtch) technique is a method which etches a semiconductor using a metal catalyst by causing the oxidation-reduction reaction on a wafer immersed in an etchant.

When metal particles are deposited on the wafer and then the wafer is immersed in the etchant, the oxidation-reduction reaction is caused on an interface of the metal and the semiconductor so that the metal gradually penetrates into the semiconductor to etch the semiconductor.

MacEtch has an anisotropic etching characteristic, but does not form a crystal damage and a plasma damage so that according to MacEtch, a semiconductor surface defect due to the etching may be minimized.

In the meantime, a front electrode of an optical device requires a high conductivity to attract electrons formed by absorbed light.

FIG. 1 is a diagram illustrating a front electrode structure of an optical device of the related art and FIG. 2 is a diagram illustrating another optical device of the related art. The optical device of FIG. 2 includes a semiconductor base 21 and an electrode 22 laminated thereon.

Such a front electrode of the optical device is applied to a solar cell or a photo detector. However, 10 to 15% of shading loss is caused due to an electrode area so that an antireflection layer or an antireflection structure needs to be formed by an additional process to absorb the light.

As described above, a large area is required to ensure a high conductivity, but light absorption to the semiconductor is reduced due to the increased front electrode so that the efficiency is reduced.

In order to avoid the trade-off relation, a transparent electrode which uses an ITO or an Ag nanowire having a high transmittance and high conductivity has been mainly studied as the front electrode. However, in order to apply the transparent electrode to the optical device, an additional process for anti-reflection is necessary.

Accordingly, there has been a demand to develop a new technology to manufacture a metal/semiconductor structure with a low reflectance and a high conductivity without performing an additional process.

### RELATED ART DOCUMENT

### Patent Document

### (Patent Document 1) Korean Unexamined Patent Application Publication No. 10-2016-0125588

### (Patent Document 2) Korean Unexamined Patent Application Publication No. 10-2016-0045306

### (Patent Document 3) Korean Registered Patent No. 10-1620981

### SUMMARY OF THE INVENTION

In order to solve the problems of the optical device manufacturing method of the related art, an object of the present disclosure is to provide a photodiode with a metal-semiconductor structure which maintains a photodiode characteristic in a metal/semiconductor junction area even after the metal-assisted chemical etching and has a low reflective and high conductive surface and a manufacturing method thereof.

Further, another object of the present disclosure is to provide a photodiode using a metal-semiconductor structure with a low reflective and high conductive surface which maintains a photodiode characteristic in a metal/semiconductor junction area and is combined with the low reflective and high conductive structural characteristic to manufacture an efficient optical device and a manufacturing method thereof.

An object of the present disclosure is to provide a photodiode using a metal-semiconductor structure with a low reflective and high conductive surface which manufactures a metal/semiconductor structure with both a low reflectance and a high conductivity only by a metal-assisted chemical etching method to simplify the manufacturing process of the optical device and a manufacturing method thereof.

An object of the present disclosure is to provide a photodiode using a metal-semiconductor structure with a low reflective and high conductive surface which performs the manufacturing process using a metal used for metal-assisted chemical etching as a front electrode without unnecessarily using metal and an additional metal removal process and a solar cell including the same.

Other objects of the present disclosure are not limited to the aforementioned object, and other objects, which are not mentioned above, will be apparently understood by the person skilled in the art from the following description.

In order to achieve the objects as described above, according to the present disclosure, a photodiode which uses a metal-semiconductor structure with a low reflective and high conductive surface includes a semiconductor substrate which includes a selectively etched electrode formation area and a light absorption area which protrudes relatively as compared with the electrode formation area; and an electrode which includes a metal catalyst layer located on the electrode formation area of the semiconductor substrate by chemically etching the semiconductor substrate and has an electrical conductivity.

In the present disclosure, a location of the light absorption area corresponds to a location of pinholes included in the metal catalyst layer and the metal catalyst layer forms a conductive metal mesh shape.

The metal catalyst layer and the semiconductor substrate maybe bonded to forma schottky junction or a PN junction. For example, in the case of the schottky junction structure, the metal catalyst is desirably shows a schottky junction characteristic.

In the present disclosure, the electrode is connected to an etching area of the antireflection semiconductor substrate in the form of a mesh and has a high conductivity. The metal catalyst layer of the electrode is formed in a location lower than the light absorption area, by the chemical etching. The semiconductor substrate includes a silicon component and has a 3D nanograss structure formed by chemically etching an area where the metal catalyst layer without the pinholes is located.

The chemical etching which is employed in the present disclosure is metal-assisted chemical etching and the semiconductor substrate includes a silicon component and at least partially includes the 3D nanograss structure formed by the metal-assisted chemical etching. The location of the light absorption area is formed at a position corresponding to a location of pinholes which are randomly distributed on the metal catalyst layer by the metal-assisted chemical etching.

In the present disclosure, a height of the light absorption area may vary depending on a requested specification of a photodiode or a solar cell. However, the height of the light absorption area may be 0.1 to 10 μm with respect to the electrode formation area. When the height of the light absorption area is too large, that is, the metal catalyst layer is deep, the electrical conductivity is lowered and when the height is too small, the reflectance is high. In the present disclosure, a diameter of a protruding portion of the silicon nanostructure may vary depending on a size of the pinhole. For example, the diameter of the protruding portion may have various values in the range of 10 nm to 200 nm.

A top portion of the light absorption area absorbs some of incident light which is incident from the outside and a wavelength range of the absorbed incident light at least partially includes a wavelength in the UV range.

In the present disclosure, the metal catalyst layer at least partially has a metal mesh structure. A surface sheet resistance (SSR) of the metal catalyst layer is desirably low. The nanograss structure of the present disclosure has a structure which suppresses the increase of the reflectance as much as possible while maintaining the surface sheet resistance to be low. The surface sheet resistance may vary depending on the requested specification of the optical device, but is desirably 2≤SSR≤10Ω/□.

Further, in the photodiode of the present disclosure, a solar weighted reflectance (SWR) and the surface sheet resistance of the metal catalyst layer satisfy 4≤SRR×SWR≤30 (%·Ω/?).

The photodiode of the present disclosure may be implemented as a short nanograss and a long nanograss. In the short nanograss, a height of the protruding portion (a height difference between the electrode formation area and the light absorption area) is 0 to 1 μm, specifically, 0.1 to 0.8 μm. In the short nanograss structure, the electron-hole pairs generated by the UV light included in the incident light from the outside are collected to the electrode through the metal catalyst layer.

In the case of the long nanograss, a height of the protruding portion is 1.5 to 10 μm, desirably, 1.5 to 7 μm, and more desirably 1.8 to 6.5 μm.

Further, in order to manufacture an optical device using a schottky junction characteristic between the high conductive electrode and the antireflection semiconductor substrate, a metal contact layer may be further formed in an area other than a low reflective and high conductive surface.

Further, the semiconductor substrate uses a material having a semiconductor characteristic selected from semiconductors of elements in group 4 including C, Si, and Ge or selected from compound semiconductors including AlAs, Alp, AlN, GaAs, GaP, GaN, InAs, InN, InP, SiC, SiGe, AlGaAs, AlGaN, AlGaP, AlInAs, AlInP, GaAsP, InGaAs, InGaN, and InGaP, and the meal catalyst may be selected from materials having a metal characteristic such as nickel (Ni, platinum (Pt), palladium (Pd), rhodium (Rh), ruthenium (Ru), zinc (Zn), silver (Ag), titanium (Ti), cobalt (Co), molybdenum (Mo), tungsten (W), aluminum (Al), iron (Fe), vanadium (V), iridium (Ir), antimony (Sb), tin (Sn), bismuth (Bi), Manganese (Mn), copper (Cu), barium (Ba), and gold (Au), but is not limited thereto.

In order to achieve the objects as described above, according to the present disclosure, a manufacturing method of a photodiode which uses a metal-semiconductor structure with a low reflective and high conductive surface includes laminating a metal catalyst layer on a semiconductor substrate; and selectively etching a semiconductor substrate which is in contact with the metal catalyst layer by chemically etching the metal catalyst layer to form an electrode with a low reflective and high conductive surface.

According to the manufacturing method of the present disclosure, the semiconductor substrate is selectively etched so that the semiconductor substrate includes a selectively etched electrode formation area and a light absorption area which protrudes relatively as compared with the electrode formation area.

In the present disclosure, in the step of forming a metal catalyst layer on the semiconductor substrate, the metal catalyst layer forms a conductive metal mesh pattern and the metal catalyst layer and the semiconductor substrate forms a schottky junction or a PN junction.

The metal catalyst layer is formed on the semiconductor substrate by depositing the metal catalyst layer on the semiconductor substrate in the form of a mesh,

The mesh shape is formed using pinholes included in the metal catalyst layer or using any one of photolithography, e-beam lithography, nanosphere lithography, and agglomeration.

In order to achieve another object, according to the present disclosure, a solar cell includes: a housing which protects internal elements of the solar cell from the outside; and a semiconductor substrate which includes a selectively etched electrode formation area and a light absorption area which protrudes relatively from the electrode formation area; and a photodiode including an electrode which includes a metal catalyst layer located on the electrode formation area of the semiconductor substrate by chemically etching the semiconductor substrate and has an electrical conductivity.

According to an exemplary embodiment of the present disclosure as described above, a photodiode having a metal-semiconductor surface with a low reflectance and a high conductive may be implemented.

Further, according to another exemplary embodiment of the present disclosure, a semiconductor optical device having a schottky photodiode characteristic in a metal/semiconductor junction area even after metal-assisted chemical etching may be implemented.

According to the manufacturing method of the present disclosure, it is possible to manufacture a metal/semiconductor structure with a low reflectance and a high conductivity only using the metal-assisted chemical etching and simplify the manufacturing steps of the optical device.

According to still another exemplary embodiment of the present disclosure, a metal used for the metal-assisted chemical etching is used as a front electrode so that unnecessary usage of the metal is reduced and an additional metal removal process is not necessary.

Further, according to still another exemplary embodiment of the present disclosure, light can be absorbed by the entire device area without causing a shading loss so that the light may be efficiently used as compared with the optical device of the related art. Further, an optical device having excellent optical and electrical characteristic as compared with a high transmissive and high conductive front electrode may be implemented.

### BRIEF DESCRIPTION OF DRAWINGS

FIGS. 1 and 2 are diagrams illustrating a front electrode structure of a normal optical device;

FIGS. 3 to 5 are diagrams for explaining a principle of a metal-assisted chemical etching method which is applied to the present disclosure;

FIGS. 6 and 7 are graphs illustrating a schottky junction characteristic and a schottky diode characteristic;

FIG. 8 illustrates a schottky photodiode structure using a metal-semiconductor structure with a low reflective and high conductive surface according to a first embodiment of the present disclosure and a manufacturing method thereof;

FIG. 9 is an electron microscopy of a surface of a schottky photodiode using a metal-semiconductor structure with a low reflective and high conductive surface according to a manufacturing process of a first embodiment;

FIG. 10 is a view illustrating a schottky photodiode structure using a metal-semiconductor structure with a low reflective and high conductive surface according to a second embodiment of the present disclosure and a process thereof;

FIG. 11 is a photograph of a surface of a schottky photodiode using a metal-semiconductor structure with a low reflective and high conductive surface manufactured by the process of FIG. 10;

FIG. 12 is a graph illustrating a sheet resistance a reflectance, and a current variation characteristic in accordance with a voltage depending on the presence of light of a low reflective and high conductive metal/semiconductor structure according to the present disclosure;

FIG. 13 is a graph of a current characteristic in accordance with a voltage and an external quantum efficiency (EQE) and responsivity in accordance with a wavelength;

FIG. 14 illustrates a photodiode structure with a silicon nanograss and an Ag mesh structure according to another exemplary embodiment of the present disclosure and a process thereof;

FIG. 15 is an electron microscopy of SiNG/Ag mesh manufactured by MacEtch according to an exemplary embodiment of the present disclosure;

FIG. 16 is a reference view illustrating a measurement result of a reflectance, a solar weighted reflectance, and a sheet resistance for an SiNG/Ag mesh according to the present disclosure;

FIG. 17 is a conceptual view for explaining an operation principle of a short nanograss and a long nanograss in accordance with a SiNG/Ag mesh structure of the present disclosure;

FIG. 18 compares results of a reflectance/absorbance/transmittance and a sheet resistance between a SiNG/Ag mesh according to an exemplary embodiment of the present disclosure, specifically a SiNG/Ag mesh in which a metal mesh structure is buried with Si as a base layer and a transparent electrode is disposed and various grids of the related art;

FIG. 19 illustrates an experiment result for a current-voltage characteristic and a photocurrent of a schottky photodiode with SiNG/Ag mesh structure of the present disclosure;

FIG. 20 illustrates an external quantum efficiency (EQE) characteristic of a SiNG/Ag mesh schottky photodiode according to an exemplary embodiment of the present disclosure; and

FIG. 21 schematically illustrates a configuration of a solar cell according to another exemplary embodiment of the present disclosure.

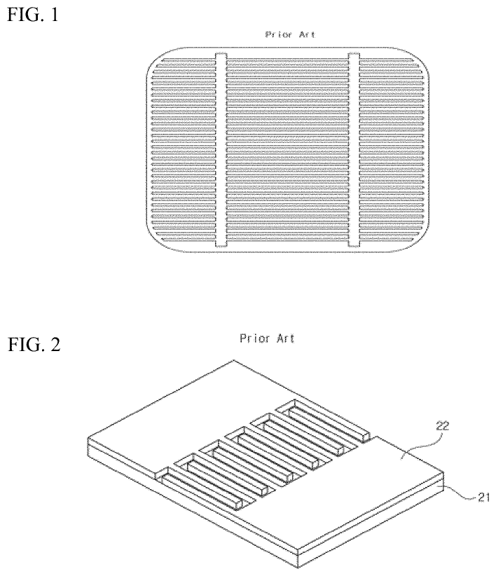

### DETAILED DESCRIPTION OF THE EMBODIMENT

Hereinafter, an exemplary embodiment of a photodiode using a metal-semiconductor structure with a low reflective and high conductive surface according to the present disclosure and a manufacturing method thereof will be described in detail as follows:

Features and advantages of the photodiode using a metal-semiconductor structure with a low reflective and high conductive surface according to the present disclosure and a manufacturing method thereof will be clear through the detailed description for the following exemplary embodiments.

The present disclosure is to form a low reflective and high conductive surface on a semiconductor such as Si or GaAs by a metal-assisted chemical etching (MacEtch) using a metal catalyst showing a schottky junction characteristic and manufacture an optical device such as a solar cell, a photodiode, or a photo detector.

In the following description, materials having a semiconductor characteristic having a conductivity between a conductivity of a conductor and a conductivity of an insulator may be used as a semiconductor substrate material and the materials may be a semiconductor of an element in group 4, such as C, Si, or Ge or a compound semiconductor of two elements (group 3+group 5 or group 2+group 6), three elements, or four elements, but are not limited thereto.

Here, the compound semiconductor may use a material having a semiconductor characteristic selected from compound semiconductors including AlAs, Alp, AlN, GaAs, GaP, GaN, InAs, InN, InP, SiC, SiGe, AlGaAs, AlGaN, AlGaP, AlInAs, AlInP, GaAsP, InGaAs, InGaN, and InGaP, but is not limited thereto.

The metal catalyst may be selected from materials having a metal characteristic such as nickel (Ni), platinum (Pt), palladium (Pd), rhodium (Rh), ruthenium (Ru), zinc (Zn), silver (Ag), titanium (Ti), cobalt (Co), molybdenum (Mo), tungsten (W), aluminum (Al), iron (Fe), vanadium (V), iridium (Ir), antimony (Sb), tin (Sn), bismuth (Bi), Manganese (Mn), copper (Cu), barium (Ba), and gold (Au), but is not limited thereto.

The schottky photodiode using a metal-semiconductor structure with a low reflective and high conductive surface according to the present invention has a structure which has a high conductivity due to the metal catalyst while lowering a reflectance, by forming a antireflection structure using a metal-assisted chemical etching method.

When light is irradiated on the diode at a reverse bias, the current is increased.

The photodiode of the present disclosure provides a low reflectance surface and a high conductance electrode. The electrode structure of the present disclosure may be obtained by the metal-assisted chemical etching process and specifically, is suitable for an electrode structure of a schottky photodiode. Silicon nanograss (SiNG) and an Ag-mesh formed by MacEtch may become a subwavelength surface and a buried electrode which is located inside, respectively. The silicon nanograss (SING) but increases light absorption without causing a shading loss and the buried Ag mesh improves the electrical conductivity.

Further, the silicon nanostructure of the present disclosure may be implemented to have a high-aspect ratio without causing crystal defects. The nanostructure of the present disclosure may be implemented by a wet based chemical process, specifically, metal-assisted chemical etching. A patterned metal catalyst is immersed in an etchant containing an acid and an oxidant to be provided on a semiconductor base. The metal catalyst generates holes through reduction reactions with the oxidant. The holes are injected into the semiconductor and the oxidized semiconductor which is in contact with the metal catalyst layer is dissolved by the acid to be removed.

According to the present disclosure, the antireflective structures manufactured by MacEtch may be modified by additional etching with selective Ag nanoparticle deposition or KOH. The light absorbance may be improved through antireflective nanotexturing. However, shading loss is inevitable in front electrodes such as busbar electrodes in solar cells or interdigitated electrodes in photodiodes. In order to minimize the shading loss, a width of the electrode may be decreased and the space may be widened, although this results in an increase in the electrical resistive loss. The present disclosure has been proposed to overcome the limitations between the shading loss and the resistive loss.

The optical device of the present disclosure has a silicon nanograss (SiNG) mesh structure which is self-organized using a metal catalyst, specifically, an Ag catalyst. When such a silicon nanograss structure is applied as an Ag—Si schottky photodiode, a low optical reflectance and a high electrical conductance may be obtained. Ag is deposited on a p-Si layer and the metal-assisted chemical etching (MacEtch) is employed to manufacture the SiNG. During the MacEtch process, pinholes are formed in the Ag layer and SiNG is patterned to have a nano size through the positions and distribution of the pinholes which are formed without the need for additional lithography process. The Ag layer has a mesh structure with pinholes and the MacEtch is performed to form a schottky junction with p-Si. The Ag layer is entirely connected in the form of a mesh to be served as an electrode with an electrical conductance.

The manufacturing process of the optical device of the present disclosure may be summarized as metal deposition and MacEtch. The optical device according to the present disclosure, that is, the photodiode overcomes the limitation of the conventional front electrode and has a high electrical conductance and a low reflectance.

The photodiode structure of the present disclosure is not limited only to the schottky junction, but may be implemented by a photodiode with a PN junction. Further, when the solar cell is implemented, as the junction between the metal catalyst and the semiconductor, both the schottky junction and the PN junction are allowed.

It is easy for those skilled in the art to implement the photodiode or the solar cell such that the metal catalyst and the semiconductor have an ohmic contact to form a PN junction.

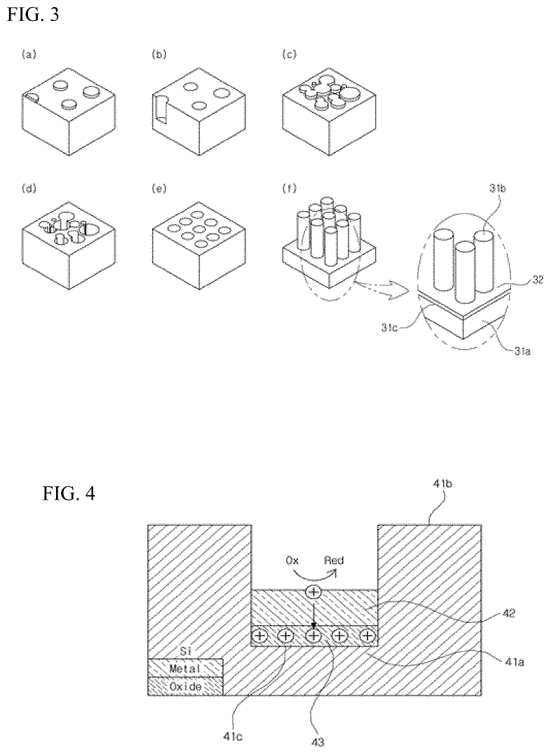

FIGS. 3 to 5 are diagrams for explaining a principle of a metal-assisted chemical etching method which is applied to the present disclosure.

First, FIG. 3 is an example illustrating various three-dimensional structure obtained using a chemical etching method. The structure of FIG. 3 may be obtained by a wet-based chemical etching method, specifically, a metal-assisted chemical etching method. When metal is deposited on a semiconductor using a wet based anisotropic semiconductor etching method and then is immersed in a solution configured by acid and oxidant, only an area of the semiconductor substrate which is in contact with the metal is etched.

The structure of FIG. 3 is merely illustrative so that the photodiode of the present disclosure may be implemented with various structures. A structure of FIG. 3F illustrates one optical device structure which may be obtained by the metal-assisted chemical etching method proposed by the present disclosure. The optical device includes a silicon base and an electrode. The silicon base is divided into an electrode formation area 31a which is buried by the etching and a light absorption area 31b which relatively protrudes. The electrode mainly includes a metal catalyst layer 32 and is buried into the silicon base by etching the electrode formation area 31a. A schottky junction area 31c is an interface area at which the electrode formation area 31a and the metal catalyst layer 32 form a schottky junction.

FIGS. 4 and 5 illustrate a structure of a photodiode obtained by a metal-assisted chemical etching according to an embodiment of the present disclosure. The photodiode of FIG. 4 includes base substrates 41a and 41b and an electrode including a metal catalyst layer 42. Here, the base substrate is a silicon substrate. The electrode may also include a wiring line to be connected to other elements in addition to the metal catalyst layer 42 and for the purpose of convenience, in the exemplary embodiment, the metal catalyst layer and the electrode may be used in combination.

The holes which are generated by the reaction of the metal catalyst layer with the oxidant moves to an etching area 43 to oxidize silicon in an area adjacent thereto (electrode formation area). Thereafter, the oxidized silicon is removed by the acid and this process is repeated to form a three-dimensional nanograss structure which is deeply dug.

An operation principle of a photodiode structure of FIG. 5 is substantially the same as the structure of FIG. 4. The photodiode of FIG. 5 includes a base substrate and a metal catalyst layer 52. The base substrate includes an electrode formation area 51a, a light absorption area 51b, and a schottky junction area 51c. The electrode formation area 51a is a lower area corresponding to a position of the metal catalyst layer and the light absorption area 51b is an area where no metal catalyst layer is provided. The area where the metal catalyst layer is not provided may refer to a pinhole area which is generated due to a limitation of a metal process or a property of the metal catalyst. Further, the area where the metal catalyst layer is not provided may be an area in accordance with a masking pattern with a predetermined pattern. The schottky junction area 51c refers to an interface between the metal catalyst layer and silicon.

According to the exemplary embodiment, holes generated by the reaction of hydrogen peroxide which is provided for etching and the metal catalyst layer 52 move to the etching area 53a to oxidize silicon which is in contact therewith.

Silicon etched by the oxidation process is removed by HF or SiF₆²⁻ injected in the etched area. This process is repeated and an etched depth may vary depending on a repeated time and the number of repeating times. The three-dimensional structure formed according to the present disclosure is a three-dimensional semiconductor structure with defect-free anisotropic etching characteristic.

In the present embodiment, the metal-assisted chemical etching method is a wet based anisotropic semiconductor etching method so that the etching is generated only in a contact area with the metal catalyst. The processes proceed by forming holes by reaction of an oxidant and metal, injecting the holes into the semiconductor to oxidize the semiconductor, and removing the oxidized semiconductor with acid.

A manufacturing method of a schottky photodiode using a metal-semiconductor structure with a low reflective and high conductive surface according to the present disclosure includes a step of depositing metal having a schottky junction characteristic on a semiconductor substrate, a step of etching the semiconductor using a metal-assisted chemical etching method which sequentially performs formation holes by reaction of an oxidant and the metal, injection of the holes into the semiconductor to oxidize the semiconductor, removal of the oxidized semiconductor with acid, and a step of manufacturing an optical device using a schottky junction characteristic between a metal and the semiconductor substrate connected in the form of mesh.

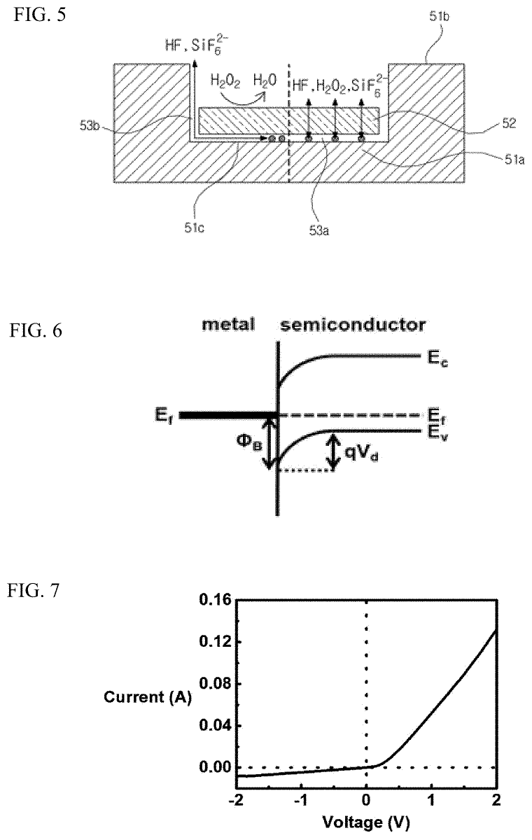

FIGS. 6 and 7 are graphs illustrating a schottky junction characteristic and a schottky diode characteristic.

The schottky junction is a junction formed by a difference of work functions of metal and a semiconductor and shows a characteristic required for a diode as a rectifying element. When a metal and a semiconductor which are bonded to show a schottky junction characteristic are used, a schottky diode which utilizes a low reflective and high conductive structure may be implemented when a structure proposed by the present disclosure is manufactured.

As described above, according to the present disclosure, in order to simplify the manufacturing process by combining a process for antireflection and a process of forming a front electrode, the metal catalyst which is used for the metal-assisted chemical etching is not removed, but is used as an electrode.

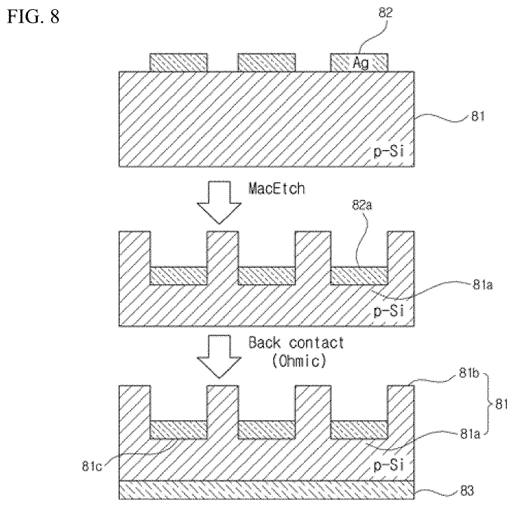

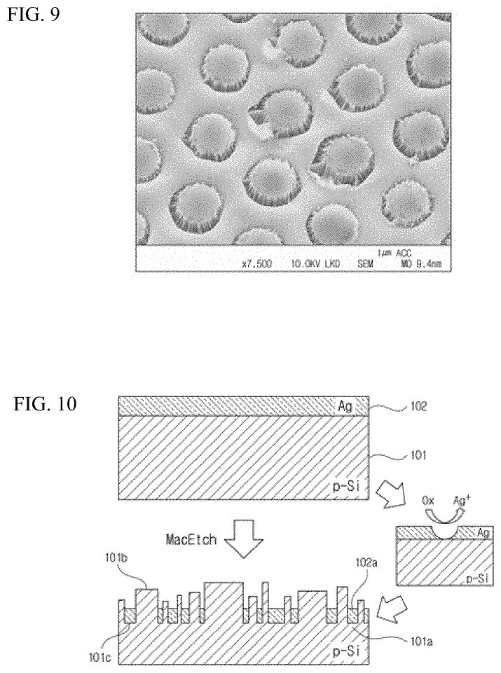

FIGS. 8 and 9 illustrate a structure of a schottky photodiode structure using a metal-semiconductor structure with a low reflective and high conductive surface according to a first embodiment of the present disclosure and a manufacturing method thereof.

A schottky photodiode using a metal-semiconductor structure with a low reflective and high conductive surface according to a first embodiment of the present disclosure includes an antireflection semiconductor substrate 81 having an electrode formation area which is selectively etched and a metal catalyst layer 82.

As seen from a viewpoint of a structure or a morphology, the semiconductor substrate 81 is divided into the electrode formation area 81a which is dug by the etching and the light absorption area 81b which is not etched. Further, the semiconductor substrate further includes a schottky junction area 81c.

The metal catalyst layer 82a which is buried on the electrode formation area 81a by the etching process entirely form at least a part of a mesh structure. That is, the metal mesh structure formed by the metal catalyst layer imparts a conductivity to a surface of the semiconductor substrate. Specifically, the three-dimensional structure according to the exemplary embodiment is an antireflective and high conductive electrode having excellent antireflection property against the incident light and excellent electric conductivity.

A manufacturing process of a schottky photodiode using a metal-semiconductor structure with a low reflective and high conductive surface according to the first embodiment with the above-described structure is as follows:

First, as illustrated in FIG. 8, a metal catalyst layer 82 having a schottky junction characteristic is deposited on a silicon semiconductor substrate 81.

Next, an area which is in contact with the metal catalyst layer 82 is etched through a metal-assisted chemical etching method (MacEtch).

The semiconductor substrate 81 is selectively etched by the above-described etching process to form a three-dimension structure which is divided into an electrode formation area and a light absorption area. The metal catalyst layer 82 used for the metal-assisted chemical etching process is located in an etched area of the semiconductor substrate having an antireflection property, that is, on the electrode formation area and is used as an electrode with a high electrical conductance.

The optical device may be manufactured using a schottky junction characteristic between a high conductive electrode 82a which is connected to the etched area of the antireflective semiconductor substrate 81 as described above, that is, the electrode formation area 81a in the mesh form and the antireflective semiconductor substrate, specifically, the electrode formation area 81a.

Further, a metal contact layer 83 may be further formed in an area other than the low reflective and high conductive surface on an opposite side of the surface of the antireflective semiconductor substrate 81. Here, the metal contact layer 83 may be an ohmic contact formed in an area other than the low reflective and high conductive surface or a schottky contact which is formed in an area other than the low reflective and high conductive surface to form a metal-semiconductor-metal schottky diode with a lower dark current and capacitance.

According to the exemplary embodiment of the present disclosure, the pinholes of the metal catalyst layer 82 are formed by a process of MacEtch. An area with the pinholes is not subjected to the metal-assisted chemical etching and remains as a nanograss column and an area of the metal catalyst layer which does not include the pinholes oxidizes the silicon substrate located therebelow. This processes are repeated to form the pinholes and perform the etching and consequently forms a metal mesh and a silicon nanograss structure.

In addition to the MacEtch, as a method for forming a metal catalyst layer 82 in the form of a mesh, there are photolithography, e-beam lithography, nanosphere lithography, and agglomeration. Further, as the metal catalyst, a metal catalyst such as Ag which shows a schottky junction characteristic on a semiconductor such as Si or GaAs. However, the silicon nanostructure which is generated by selective etching between an area with pinholes and an area which does not include pinholes is more advantageous because a nano size structure can be manufactured without the need of the above-described separate process.

The metal catalyst layer of the present disclosure forms a conductive surface. The metal catalyst layer has a metal mesh structure formed by MacEtch. A surface sheet resistance (SSR) of the metal catalyst layer may vary depending on a requested specification of the optical device or the solar cell. Desirably, 2≤SSR≤10Ω/□. When the resistance is smaller than the reference value, there is a limitation in that the resistive characteristic is excellent but the reflectance is increased. If the resistance is higher than the reference value, there is a limitation of an energy loss in accordance with a high resistance.

A surface reflectance or a solar weighted reflectance of a photodiode with a silicon nanograss structure and a metal mesh structure of the present disclosure may have various values according to a specification requested by the optical device. When the schottky photodiode is considered, the SWR is desirably 0.5≤SWR≤15%. If the solar weighted reflectance is smaller than the reference value, the reflection loss is small but the resistance is increased and if the solar weighted reflectance is larger than the reference value, an optical reflective loss is too high. A relationship between an electrical conductivity and a surface reflectance of the photodiode of the present disclosure in which a silico nanograss structure and a metal mesh with a structure which is buried by the etching are combined is basically a trade-off relationship. However, according to the present disclosure, the problems of the related art due to the trade-off may be improved by the silicon nanograss structure through the metal-assisted chemical etching.

SWR and SSR may vary depending on the specification requested by the optical device and have a value in the range of 4≤SWR×SSR≤30 (%·Ω/□). The physical property parameter is derived by an electrical conductive and antireflective properties of the silicon nanograss and in this specification, it is referred to as an optical detection loss rate.

If an optical detection efficiency rate is lower than 4, there is a problem in that a deviation between the electrical conductance and the reflectance is large or at least one of the conductance and the reflectance is too low. Further, if the optical detection efficiency rate is larger than 30, the efficiency may be lowered due to the excessively high reflectance.

According to the present disclosure, the optical detection loss rate tends to decrease in accordance with the time of MacEtch and the rate may be lowered below the range of 2 to 4, but the resistive loss is disadvantageously increased. Accordingly, in the range therebelow, that is, in the case of the optical device which requires a high optical absorption despite the resistive loss, the optical detection loss rate may be configured to be lower.

During the researching process for a silicon nanostructure of the present disclosure, a SiNG/Ag mesh structure manufactured according to the exemplary embodiment of the present disclosure has a solar weighted reflectance of 1.2% and a sheet resistance of 5.48Ω/□. The schottky photodiode with the SiNG/Ag mesh structure shows an external quantum efficiency of 89.5% with respect to light in a wavelength of 860 nm and has an internal photoemission effect in a sub-band gap. A self-organized SiNG/Ag mesh may be manufactured by a simplified wet-etching method. Since the SiNG/Ag mesh is optimized in view of both the optical and electrical losses, according to the present disclosure, a range of the optical device such as a photodiode or an optical electronic device may be widened.

FIG. 9 is a photograph of a surface of a schottky photodiode using a metal-semiconductor structure with a low reflective and high conductive surface according to a manufacturing process of a first embodiment.

FIG. 10 is a view illustrating a schottky photodiode structure using a metal-semiconductor structure with a low reflective and high conductive surface according to a second embodiment of the present disclosure and a process thereof.

A schottky photodiode using a metal-semiconductor structure with a low reflective and high conductive surface according to a second embodiment of the present disclosure includes an antireflection semiconductor substrate having an electrode formation area 101a which is selectively etched and a metal catalyst layer 102a formed by placing a metal catalyst used for a metal-assisted chemical etching process employed to form a three-dimensional nanograss structure of the antireflection semiconductor substrate in an etching area of the antireflection semiconductor substrate, that is, a high conductive electrode. An interface between the metal catalyst layer and the electrode formation area is a schottky junction area 101c.

A manufacturing process of a schottky photodiode using a metal-semiconductor structure with a low reflective and high conductive surface according to the second embodiment with the above-described structure is as follows:

First, after depositing the metal catalyst layer 102 having a schottky junction characteristic on the semiconductor substrate 101 without patterning, a metal is manufactured as a mesh pattern using a fact that the metal is easily ionized in a solution having a high oxidant concentration and the semiconductor substrate 101 is etched to implement an antireflection semiconductor substrate, simultaneously.

As described above, a high conductive electrode is formed by placing the metal catalyst used for the metal-assisted chemical etching process for forming an antireflection semiconductor substrate in the etching area (the electrode formation area 101a) of the antireflection semiconductor substrate.

As a result, a three-dimensional structure with an ultra-wavelength is formed to lower the reflectance and the high conductive electrode is connected in the form of mesh to show a high electrical conductivity.

The schottky photodiode characteristic is maintained in a metal/semiconductor junction area even after the metal-assisted chemical etching and an optical device may be efficiently manufactured in combination of a low reflective and high conductive structural characteristic.

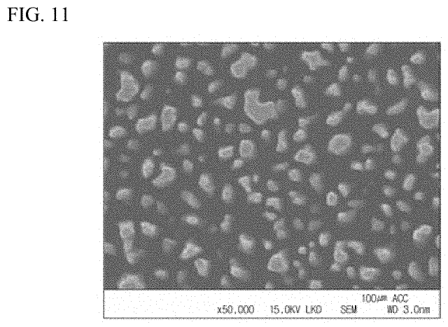

FIG. 11 is a photograph of a surface of a schottky photodiode using a metal-semiconductor structure with a low reflective and high conductive surface manufactured by the process of FIG. 10.

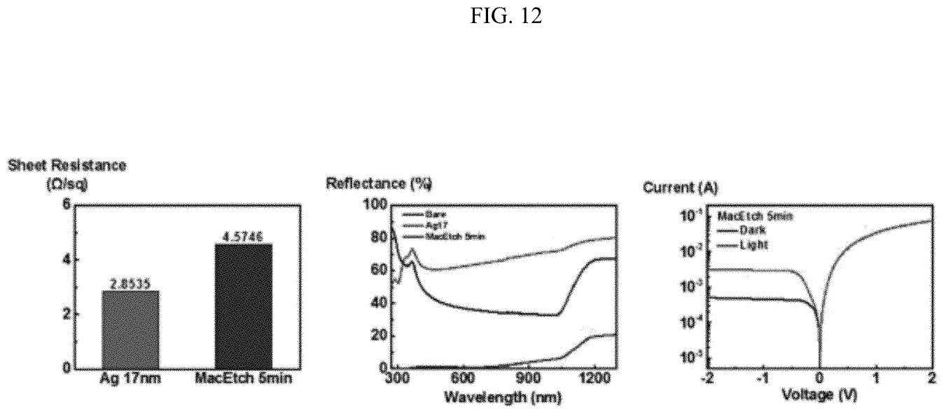

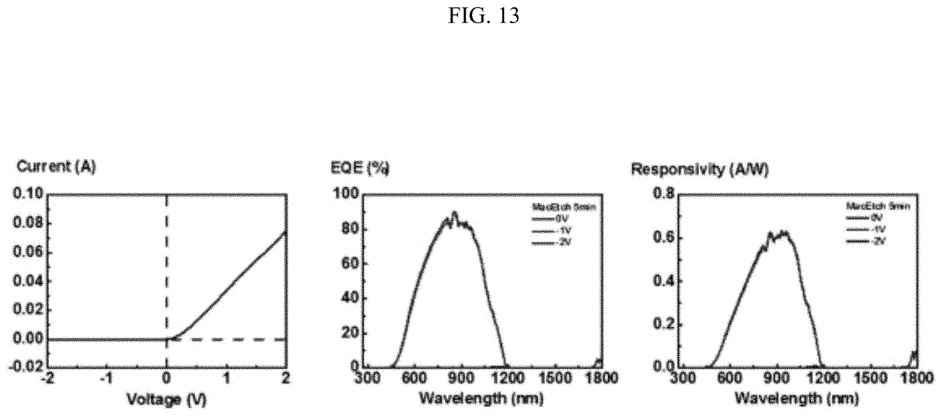

FIG. 12 is a graph illustrating a sheet resistance, a reflectance, and a current variation characteristic in accordance with a voltage depending on the presence of light of a low reflective and high conductive metal/semiconductor structure according to the present disclosure, and FIG. 13 is a graph of a current characteristic in accordance with a voltage and an external quantum efficiency (EQE) and responsivity in accordance with a wavelength.

As a result of I-V measurement, a diode characteristic is confirmed and a characteristic of a photodiode, that is, a photodetector that current increases in the presence of light is also confirmed.

As a measurement result of external quantum efficiency and responsivity, it is confirmed that it is detected in the range of 500 to 1200 nm and 1750 to 1800 nm.

A schottky photodiode using a metal-semiconductor structure with a low reflective and high conductive surface according to the present disclosure described above and a manufacturing method thereof are to manufacture an optical device such as a solar cell or a photodetector while forming a low reflective and high conductive surface through metal-assisted chemical etching on a semiconductor such as Si or GaAs using a metal catalyst showing a schottky junction characteristic. To this end, the manufacturing process is performed using a metal used for the metal-assisted chemical etching as a front electrode without unnecessarily using a metal and performing an additional metal removal process while maintaining the schottky photodiode characteristic in the metal/semiconductor junction area even after the metal-assisted chemical etching.

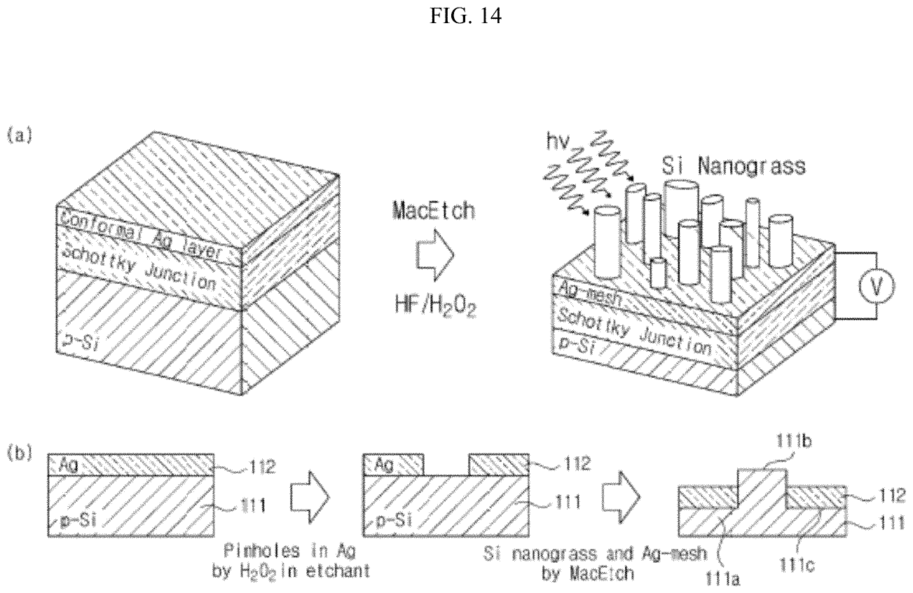

FIG. 14 illustrates a photodiode structure with a silicon nanograss and silver mesh structure according to another exemplary embodiment of the present disclosure and a process thereof.

In the process of a photodiode of FIG. 14, the silicon nanograss is formed by the metal-assisted chemical etching performed by pinholes present in silver or metal catalyst without performing lithography patterning. The pinholes are further formed by the metal-assisted chemical etching.

Here, the metal-assisted chemical etching is performed in a situation in which HF or H₂O₂ is supplied on a Ag catalyst layer. The schottky junction is formed at an interface of an Ag mesh layer corresponding to the metal catalyst layer and a p-Si layer corresponding to the semiconductor substrate. Pinholes which are randomly distributed are generated in the HF/H₂O₂ solution through ionization and redistribution of the Ag catalyst. Nanoscale etching (nanoscale MacEtch) in accordance with the metal catalyst occurs in the pinholes of the Ag mesh, which results in a silicon nanograss surface.

FIG. 14A illustrates a concept of a manufacturing process of antireflection and conductive SiNG/AG mesh using the above-described MacEtch. A schottky junction with a barrier voltage of 0.68 eV is formed after depositing an Ag metal catalyst layer with a thickness of 17 nm and annealing the Fermi level to be an equilibrium state. The Ag-on-Si structure is formed by a process of immersing into an etchant composed of HF and H₂O₂.

FIG. 14B illustrates details included in a SiNG forming process. When the thickness of the metal catalyst layer is in the range of 5 to 20 nm, the plurality of pinholes are continuously formed on the metal catalyst layer during the MacEtch process by ionization and redistribution. Next, an area where the MacEtch is performed is an area where the metal catalyst layer is in contact with a silicon base layer.

The MacEtch process may be implemented as follows: First, H₂O₂ reacts with Ag to form holes. Here, the holes are injected into the Si semiconductor to oxidize silicon. Thereafter, the oxidized Si is removed by HF. During the immersion of the etchant in the Ag metal catalyst layer, the pinhole forming process and the MacEtch process are simultaneously or non-simultaneously performed and as a result, a SiNG (silicon nanograss) structure with a random distribution is implemented by combining two processes. In such a silicon nanograss structure, a protruding portion (a light absorption area) may be formed with various heights and diameters. External incident light is absorbed at a tip of the protruding portion. Specifically, it is suitable for absorption of light in an UV range.

In a typical etching process, a thin layer of the metal catalyst layer may be patterned on the semiconductor and the nanostructure is manufactured by selective etching. Here, the selective etching is performed in an area where the metal catalyst is in contact with the semiconductor substrate. However, in the present disclosure, MacEtch of SiNG is performed without the need of lithography patterning. The pattern is formed by the pinholes included in the metal catalyst layer. The SING according to the present disclosure significantly lowers the light reflectance and the Ag metal catalyst layer, that is, the Ag mesh improves the electrical conductance. The SiNG/Ag-mesh structure which is acquired as a result is highly antireflective and conductive.

The photodiode with a silicon nanograss structure manufactured by FIG. 14 includes a silicon semiconductor substrate 111 and an electrode 112 including a metal catalyst layer. The silicon semiconductor substrate includes an electrode formation area 111a, a light absorption area 111b, and a schottky junction area 111c.

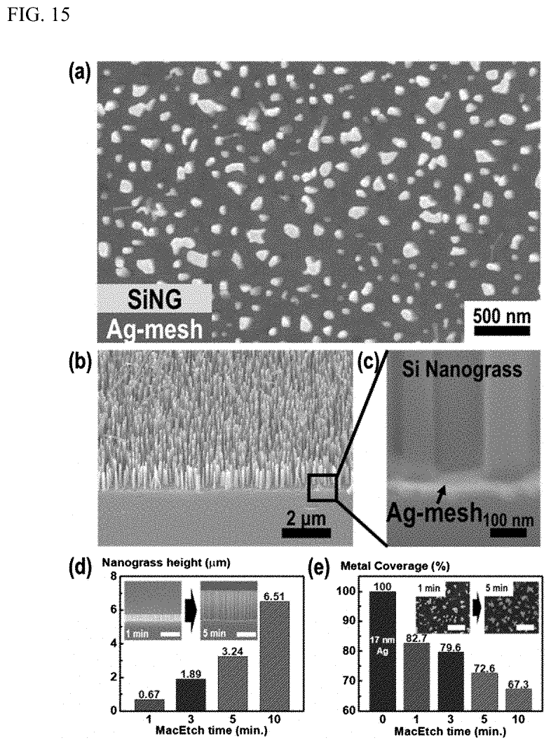

FIG. 15 is an electron microscopy of SING/AG mesh manufactured by MacEtch according to an exemplary embodiment of the present disclosure. The result of FIG. 15 represents a self-organized SiNG/Ag mesh which is acquired after performing MacEtch for 3 minutes. In FIG. 15A, a bright color part indicates a silicon nanograss array and a dark color part indicates an Ag mesh electrode. FIG. 15B is a photograph in a direction tilted at 25 degrees and FIG. 15C is a photograph of an enlarged cross-sectional view of a SiNG/Ag mesh. A bright area on a bottom of SiNG is an Ag mesh (a Ag mesh metal catalyst layer). As the MacEtch proceeds, a height of SiNG increases at a rate of 0.65 μm/min. The inserted drawing shows a size of the nanograss and a size of a scale bar is 2 μm.

The SiNG has a subwavelength structure which reduces the reflectance by continuous change of refractive index. The Ag mesh retains its electrical conductivity after performing the MacEtch because the Ag metal catalyst layer is connected in the form of a continuous mesh grid.

As illustrated in FIG. 15D, the height of the SiNG substantially linearly increases in accordance with the MacEtch time. A density of the SiNG increases depending on the MacEtch time with respect to a planar direction of the photodiode. In the present embodiment, an etch rate is almost constant at approximately 0.65 μm/min, which means that the height of the resulting SiNG can be precisely controlled.

FIG. 15E illustrates that a metal coverage of the Ag mesh to the SiNG is decreased in accordance with the MacEtch time. The inserted drawing shows a size of the nanograss and a size of a scale bar is 500 μm. The metal surface coverage increases in accordance with the MacEtch because additional pinholes are formed by the MacEtch.

In the structure of the present disclosure, the metal surface coverage is desirably 40 to 90%, specifically, 60% to 90%. When the metal surface coverage exceeds 90%, there is a problem in that the electrical conductivity is slightly improved, but the reflectance is high. Further, when the metal surface coverage is lower than 50%, the reflectance is slightly reduced, but the electrical conductivity is low.

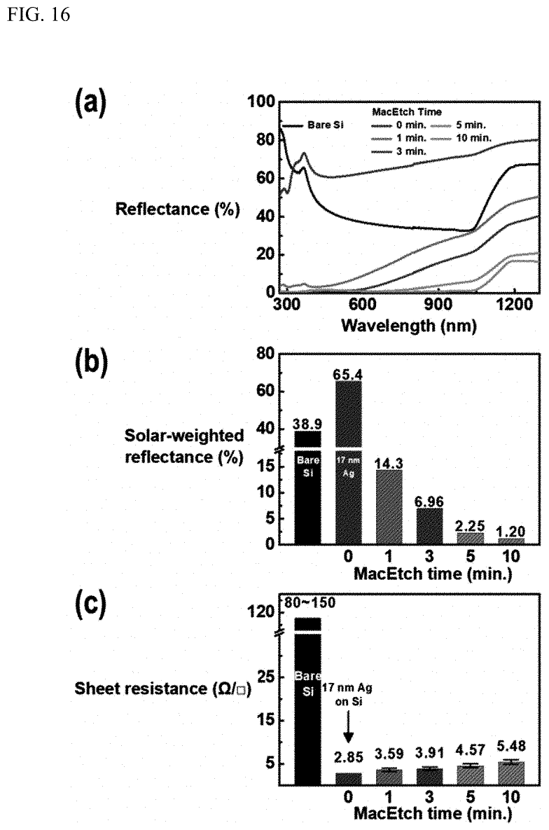

FIG. 16 is a reference view illustrating a measurement result of a reflectance, a solar weighted reflectance, and a sheet resistance for an SiNG/AG mesh according to the present disclosure.

The results in FIG. 16 are results for silicon (bare Si), Ag-on-Si in which 17 nm-thick silver is laminated, and an SiNG/Ag mesh acquired by the MacEtch according to the present disclosure, respectively. A spectral range of a light wavelength is 270 to 1300 nm.

FIG. 16A illustrates reflectance results. A high shading loss of the Ag-on-Si structure is significantly reduced in accordance with UV-visible-BIR wavelengths after forming the SiNG/Ag mesh via the MacEtch. As the size of the silicon nanograss increases, the reflectance is significantly reduced. The SiNG/Ag mesh has a very low reflectance in a UV region, experimentally, a low reflectance of 0.5 to 7%. In contrast, the reflectances in the visible range and the NIR regions are gradually reduced. In consideration of this, it is desirable to design the device in the range of 0.5 to 15%, especially, 0.5 to 10% of a reflectance in the UV region. In order to reduce the reflectance to be lower than 0.5%, the formation of the electrode needs to be minimized. However, in this case, there is a problem in that a sheet resistance is significantly increased. When the reflectance is higher than 15%, a reduction width of the sheet resistance is small, but an optical loss is caused in accordance with the reflection.

When the reflectance measured across the solar spectrum is compared, a solar weighted reflectance (SWR) is calculated. FIG. 16B represents a reflectance weighted according to the AMI.5G standard solar spectrum which is significantly increased in accordance with the increase of the MacEtch time.

FIG. 16C is a graph illustrating sheet resistances of the Ag-on-Si and the SiNG/Ag mesh. After the MacEtch, the electrical resistance of the SiNG/Ag mesh is much lower than that of the bare Si and is similar to that of the 17 nm-thick Ag-on-Si. The low sheet resistance and the low solar weighted reflectance are advantageous to collect carriers of front-illuminated photodiodes. A sheet resistance of the SiNG/Ag mesh structure according to the exemplary embodiment is desirably 2 to 10Ω/□. When the sheet resistance is lower than 2Ω/□, the surface reflectance is too high. Further, when the sheet resistance is higher than 10Ω/□, the loss is increased in accordance with the high sheet reflectance despite the advantage of the low surface reflectance.

The increase in the sheet resistance after the MacEtch is associated with the reduced metal surface coverage due to the pinhole formation. The sheet resistance of the SiNG/Ag mesh increases to 5.48Ω/□ after the MacEtch process for 10 minutes, which is approximately two times of the 17 nm-thick Ag-on-Si. This indicates that the SiNG/Ag mesh grid manufactured via the MacEtch has a low reflectance (SWR) of 1.2% and a low sheet resistance of 5.48Ω/□ and it shows an optimal performance in consideration of both the optical loss and the electrical loss.

As illustrated in FIGS. 16B and 16C, there is a trade-off between the SWR and the sheet resistance depending on the MacEtch time. The balance of the SWR and the sheet resistance may be determined according to power consumption and photoelectric conversion efficiency in a particular system.

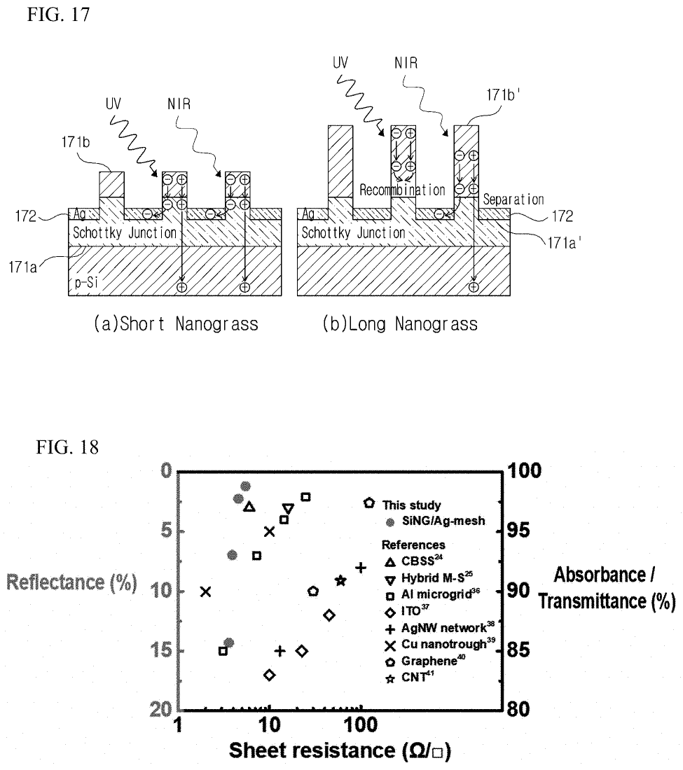

FIG. 17 is a conceptual view for explaining an operation principle of a short nanograss and a long nanograss in accordance with a SiNG/Ag mesh structure of the present disclosure.

A short nanograss structure is obtained by the MacEtch for 0.5 to 2.5 minutes and a long nanograss structure is obtained by the MacEtch for 2.5 minutes or longer, desirably, for 2.5 to 15 minutes.

A structure of FIG. 17A is obtained by the MacEtch for approximately 1 minute and a structure of FIG. 17B is obtained by the MacEtch for 5 minutes. FIG. 17 explains a light absorbing operation when light is irradiated to a short or long SiNG structure.

The short nanograss of FIG. 17A includes a semiconductor substrate including an electrode formation area 171a and a light absorption area 171b and an electrode of a metal catalyst layer 172. The long nanograss of FIG. 10B includes a structure of a light absorption area 171b′, an electrode formation area 171a′, and a metal catalyst layer 172 which are formed to be higher than that of FIG. 17A.

A short wavelength photon is primarily absorbed at the tip of the nanograss. In the short nanograss, electron-hole pairs generated by UV light are collected to the electrode through a short path. In the long nanograss, the electron-hole pairs tend to be recombined before reaching the schottky junction.

The UV light generates electron-hole pairs mostly in a top portion (a tip of the light absorption area) of the protruding portion of the SiNG. This is because the UV light has a low penetration characteristic in the SiNG structure. In the short SiNG nanograss, carries generated by the UV light are separated by the schottky junction and are collected before recombination. The carriers generated by the NIR light are easily separated due to a short distance from the schottky junction. A gradual reduction of EQE is attributable to a relatively high reflectance of the short nanograss in the NIR region, as illustrated in FIG. 17A.

In contrast, in the case of a long nanograss, that is, a long SiNG structure, the electron-hole pairs generated by the UV light tends to be recombined before reaching the junction. The surface recombination process is not prevented due to the large surface area of the long nanograss. In the silicon nanostructure, a passivation layer suppresses the surface recombination and increases a carrier diffusion length. In the long nanograss structure, the UV response may be enhanced by the passivation layer. As the wavelength increases, the light may penetrate deeper and more electron-hole pairs are generated to be located in the vicinity of the schottky junction.

The long nanograss structure reduces the reflectance, absorbs more light in the NIR region, which results in a high EQE characteristic. However, in the case of a short wavelength, it is not easy to reach a deeper schottky junction in a longer SiNG structure. Therefore, the EQE peak is red-shifted and increased in accordance with the MacEtch time.

FIG. 18 compares results of a reflectance/absorbance/transmittance and a sheet resistance between a SiNG/Ag mesh according to an exemplary embodiment of the present disclosure, specifically a SiNG/Ag mesh in which a metal mesh structure is buried with Si as a base layer and a transparent electrode is disposed and various grids of the related art.

The SiNG/Ag mesh structure of the present disclosure has a low solar-weighted reflectance (SWR) of 1.2 to 14.3% and a low sheet resistance of 3.59 to 5.48Ω/□. Even though the surface coverage (60 to 90%) of the Ag mesh is much higher than that of the front electrode of the related art, the reflectance is significantly reduced. This is because the SiNG has an antireflection property, a height of the SiNG is advantageous to absorb the incident light, and a silicon nano protruding portion of the SiNG covers the Ag mesh area which is buried therein. According to the above-described operation, the SiNG/Ag mesh structure of the present embodiment reduces both the shading loss and the electrical loss. According to the present disclosure, the Ag mesh layer is not removed, but is used for an electrode for collecting carriers.

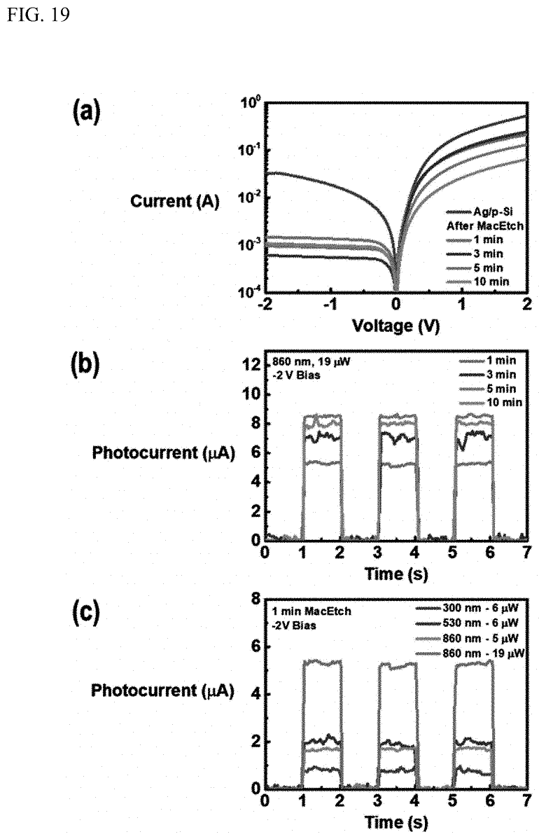

FIG. 19 illustrates an experiment result for a current-voltage characteristic and a photocurrent of a schottky photodiode with SiNG/Ag mesh structure of the present disclosure.

FIG. 19A is an experiment result of a current-voltage characteristic of Ag-on-Si and a SiNG/AG mesh schottky diode according to an exemplary embodiment of the present disclosure under a dark condition. Reverse/forward currents are reduced in proportion with the MacEtch time due to the changes in the effective area and an interface state of the Ag mesh. FIG. 19B illustrates a photocurrent of the SiNG/Ag mesh when pulsed light with a wavelength of 860 nm with an intensity of 19 μW is applied to the front illuminated photodiode, at a reverse-biased voltage of −2V.

As the MacEtch time increases, the reflectance is reduced and the photocurrent generated by the absorbed light increases. However, a photocurrent of the SiNG/Ag mesh obtained by the MacEtch process for 10 minutes was measured to be lower than that of the SiNG/Ag mesh obtained by the MacEtch process for 5 minutes. As the length of the silicon nanograss increases, responsivity of incident light absorbed by the nano protrusion structure of SiNG is lowered before reaching the junction area.

FIG. 19C illustrates a photocurrent value in accordance with a wavelength and a power. The SiNG surface increases light absorption and electron-hole pairs are diffused to the Ag mesh to be collected as a photocurrent.

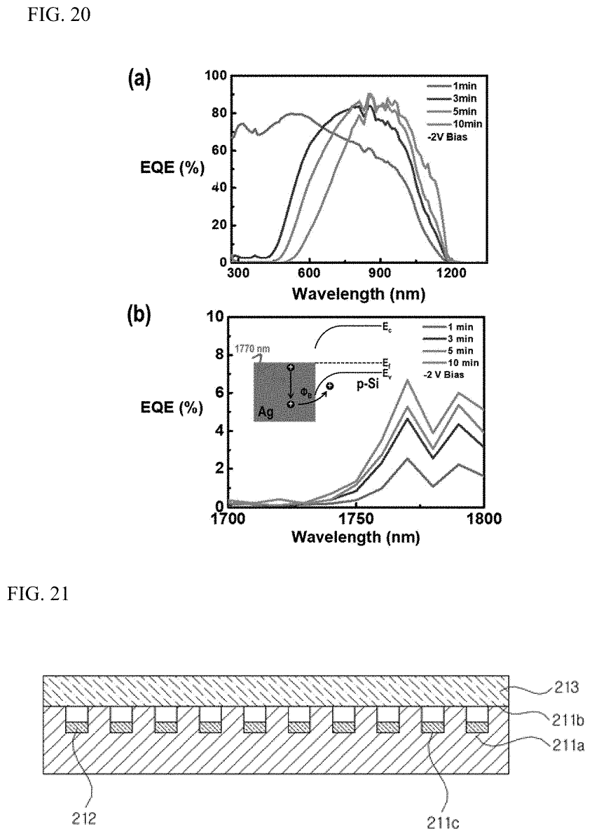

FIG. 20 illustrates an external quantum efficiency (EQE) characteristic of a SiNG/Ag mesh schottky photodiode according to an exemplary embodiment of the present disclosure. Specifically, FIG. 20A illustrates an external quantum efficiency in a wavelength of 270 to 1300 nm and FIG. 20B illustrates an external quantum efficiency in a wavelength of 1700 to 1800 nm. The inserted drawing illustrates a sub-band gap EQE for the photo detection of 1750 to 1800 nm wavelength. Holes in Ag excited by the NIR light is similar to a height of a schottky barrier and drift to a p-Si substrate cross the schottky barrier.

In FIG. 20A, the EQE in the UV region is reduced in accordance with the MacEtch time and is red-shifted to a longer wavelength. The maximum EQE may slightly increase. The response in the short wavelength band is reduced in accordance with the surface recombination. In the photodiode with the SiNG/Ag mesh structure, it is interpreted as a result of a longer diffusion distance.

In FIG. 20B, photons with energy lower than a band gap are not captured, but the internal photoemission effect in the sub-bandgap is observed in the wavelength of 1750 to 1800 nm. The EQE value is increased from 2.53% to 6.67% as the MacEtch time increases, in a specific wavelength of 1770 nm. At the metal/semiconductor schottky junction, the carriers in the metal area are injected to the semiconductor by absorbing the light with an energy of the schottky barrier. The NIR light with a wavelength of 1770 nm is approximately 0.70 eV corresponding to a schottky barrier height of a Ag/p-Si junction. The SiNG/Ag mesh shows a photodetection characteristic in the sub-band gap, which is one of characteristics of the schottky photodiode. Therefore, when the structure of the present disclosure is used, a photodiode with a specific wavelength in the IR region may be implemented using an appropriate combination of the semiconductor and the schottky metal.

FIG. 21 schematically illustrates a configuration of a solar cell according to another exemplary embodiment of the present disclosure. A solar cell illustrated in FIG. 21 includes a housing 213, silicon substrates 211a, 211b, and 211c, and an electrode 212 of a metal catalyst layer.

The housing protects elements, such as a schottky junction photodiode or a PN junction diode, in the solar cell from the outside. The photodiode which is configured by a silicon substrate and an electrode has been described above, so that a common description will be omitted.

The above-described experimental result was carried out for a photodiode with a SiNG/Ag mesh structure obtained by the following manufacturing example. The following fabrication example proposes an exemplary embodiment of the present disclosure so that the scope of the present disclosure is not limited to this example.

### [Fabrication Example]

A semiconductor substrate used to manufacture a SiNG/Ag mesh was a boron-doped p-type Si (100) substrate with a thickness of 660 to 690 μm and a resistivity of 5 to 10Ω/cm. The Si substrate was diced to a dimension of 2×2 cm² and was cleaned with acetone, isopropanol (IPA), and deionized water for 5 minutes each. After removing impurity (native oxide) with a buffered oxide etchant (BOE), a 17 nm-thick Ag layer was deposited at a rate of 2 Å/s by a thermal evaporator.

The MacEtch etchant was prepared by mixing 40 ml of hydrofluoric acid (HF, 48%), 12 ml of hydrogen peroxide (H₂O₂, 32%), and 160 ml of deionized water (DI) 160 ml for 30 minutes. The MacEtch was conducted for 1, 3, 5, and 10 minutes by adding the mixed etchant. After the MacEtch, back contracts were formed by depositing a 100 nm-thick Pt layer on a back surface of a Si substrate through DC sputtering.

### [Experiment Method]

A morphology and an etching depth of the SiNG/Ag mesh structure were examined through FE-SEM. A metal surface coverage of the SiNG/Ag mesh was measured by ImageJ software (NIH, http://imagej.nih.gov/ij/) using top-view SEM images. A UV-Vis-NIR spectrophotometer was used to measure a reflectance in a wavelength range of 270 to 1300 nm. After forming contact pads with an Ag paste at four corners of the diced substrate, a sheet resistance was measured via the Van der Pauw using a hall measurement system.

All samples were diced to have a size of 2.0 cm×2.0 cm, and the area of the Ag paste contacts formed in each sample was fairly and accurately measured using ImageJ software. The area of Ag-paste contacts for each sample was calculated to be 0.14 to 0.18 cm², which are considerably smaller than the sample area of 4.0 cm². The nanoholes produced in the present embodiment are uniformly distributed on the Ag mesh surface.

The current-voltage curve was measured in the range of −2 to +2 V under the dark condition, by a power device analyzer (Agilent B1505A). Pulsed light responses were measured using a Hg/Xe lamp, a monochromator, and a semiconductor characterization system (Keithley 4200).

The EQE was measured in the range of 270 to 1800 nm using a quantum efficiency measurement system (PV measurement, QEX-10). Porous nanograss may act as recombination sites of carriers due to incomplete chemical bonds in the crystals to reduce the photoelectric conversion efficiency. On the other hand, the amorphous property of porous Si nanograss may increase the photoelectric conversion efficiency by obtaining a direct band gap structure. All characteristics were conducted within 7 days after MacEtch.

Even though The above-described embodiment is an example which focuses on a photodiode with a schottky junction, it is obvious that the right interpretation of the photodiode structure of the present disclosure is not limited to the schottky junction, but includes a photodiode with a PN junction. Further, when the solar cell is implemented, as the junction between the metal catalyst and the semiconductor, both the schottky junction and the PN junction are allowed. Furthermore, it is easy for those skilled in the art to implement the photodiode or the solar cell such that the metal catalyst and the semiconductor have an ohmic contact to form a PN junction, based on the above-described embodiment.

As described above, it will be understood that the present disclosure is implemented in a modified form without departing from the essential characteristics of the present disclosure.

Therefore, the specified embodiments should be considered from a descriptive point of view rather than a limiting point of view and the scope of the present disclosure is represented in the claims rather than the above description and all differences within a scope equivalent thereto is interpreted to be included in the present disclosure.

What is claimed is:

1. A photodiode, comprising:
a semiconductor substrate which includes a selectively etched electrode formation area and a light absorption area which protrudes relatively as compared with the electrode formation area; and
an electrode which includes a metal catalyst layer located on the electrode formation area of the semiconductor substrate by chemically etching the semiconductor substrate and has an electrical conductivity.

2. The photodiode according to claim 1, wherein the metal catalyst layer at least partially has a metal mesh structure and the chemical etching is metal-assisted chemical etching.

3. The photodiode according to claim 1, wherein the chemical etching is a metal-assisted chemical etching and the semiconductor substrate includes a silicon component and at least partially includes a 3D nanograss structure formed by the metal-assisted chemical etching, a position of the light absorption area is formed at a position corresponding to a position of pinholes which are randomly distributed on the metal catalyst layer by the metal-assisted chemical etching, and the electrode formation area forms a schottky junction with a remaining area of the metal catalyst layer in which pinholes are not provided.

4. The photodiode according to claim 1, wherein a height of the light absorption area is 0.1 to 10 μm from the electrode formation area, and a top portion of the light absorption area absorbs some of incident light which is incident from the outside and a wavelength range of the absorbed incident light at least partially includes a wavelength in the UV range.

5. The photodiode according to claim 3, wherein the metal catalyst layer at least partially has a metal mesh structure and a surface sheet resistance (SSR) of the metal catalyst layer is 2≤SSR≤10Ω/□, and a solar weighted reflectance (SWR) and the surface sheet resistance of the metal catalyst layer satisfy 4≤SSR×SWR≤30 (%·Ω/□).

6. The photodiode according to claim 1, further comprising:
a metal contact layer formed in an area other than the surface.

7. The photodiode according to claim 1, wherein the semiconductor substrate uses a material having a semiconductor characteristic selected from semiconductors of elements in group 4 including C, Si, and Ge or selected from compound semiconductors including AlAs, Alp, AlN, GaAs, GaP, GaN, InAs, InN, InP, SiC, SiGe, AlGaAs, AlGaN, AlGaP, AlInAs, AlInP, GaAsP, InGaAs, InGaN, and InGaP, and the metal catalyst layer is selected from materials having a metal characteristic such as nickel (Ni), platinum (Pt), palladium (Pd), rhodium (Rh), ruthenium (Ru), zinc (Zn), silver (Ag), titanium (Ti), cobalt (Co), molybdenum (Mo), tungsten (W), aluminum (Al), iron (Fe), vanadium (V), iridium (Ir), antimony (Sb), tin (Sn), bismuth (Bi), Manganese (Mn), copper (Cu), barium (Ba), and gold (Au).

8. The photodiode according to claim 1, wherein the chemical etching is metal-assisted chemical etching and the semiconductor substrate includes a silicon component and at least partially includes a 3D nanograss structure formed by the metal-assisted chemical etching, and a height of the nanograss is adjusted by the time of the metal-assisted chemical etching.

9. The photodiode according to claim 8, wherein when the height of the nanograss is 0.1 to 0.8 μm, electron-hole pairs generated by UV light included in incident light from the outside are collected in the electrode by the metal catalyst layer.

10. The photodiode according to claim 1, wherein a metal surface coverage rate of the photodiode in accordance with the metal catalyst layer is 60 to 90%.

11. A manufacturing method of a photodiode, comprising:
laminating a metal catalyst layer on a semiconductor substrate; and
selectively etching a semiconductor substrate which is in contact with the metal catalyst layer by chemically etching the metal catalyst in which consequently, the semiconductor substrate is etched to have an electrode formation area formed by the etching and a light absorption area which protrudes relatively as compared with the electrode formation area.

12. The manufacturing method of a photodiode according to claim 11, wherein the metal catalyst layer at least partially has a metal mesh structure and the chemical etching is metal-assisted chemical etching.

13. The manufacturing method of a photodiode according to claim 11, wherein the chemical etching is a metal-assisted chemical etching and the semiconductor substrate includes a silicon component and at least partially includes a 3D nanograss structure formed by the metal-assisted chemical etching, a position of the light absorption area is formed at a position corresponding to a position of pinholes which are randomly distributed on the metal catalyst layer by the metal-assisted chemical etching, and the electrode formation area forms a schottky junction with a remaining area of the metal catalyst layer in which pinholes are not provided.

14. The manufacturing method of a photodiode according to claim 11, wherein a height of the light absorption area is 0.1 to 10 μm with respect to the electrode formation area, a top portion of the light absorption area absorbs some of incident light which is incident from the outside and a wavelength range of the absorbed incident light at least partially includes a wavelength in the UV range, and the metal catalyst layer at least partially has a metal mesh structure and a surface sheet resistance (SSR) of the metal catalyst is 2≤SSR≤10Ω/□, and a solar weighted reflectance (SWR) and the surface sheet resistance of the metal catalyst layer satisfy 4≤SRR×SWR≤30 (%·Ω/□).

15. The manufacturing method of a photodiode according to claim 11, wherein the metal catalyst layer is formed on the semiconductor substrate by depositing the metal catalyst layer on the semiconductor substrate in the form of a mesh, the mesh shape is formed using pinholes included in the metal catalyst layer or by patterning a metal catalyst using any one of photolithography, e-beam lithography, nanosphere lithography, and agglomeration.

16. The manufacturing method of a photodiode according to claim 11, wherein the semiconductor substrate uses a material having a semiconductor characteristic selected from semiconductors of elements in group 4 including C, Si, and Ge or selected from compound semiconductors including AlAs, Alp, AlN, GaAs, GaP, GaN, InAs, InN, InP, SiC, SiGe, AlGaAs, AlGaN, AlGaP, AlInAs, AlInP, GaAsP, InGaAs, InGaN, and InGaP, and the metal catalyst layer is selected from materials having a metal characteristic such as nickel (Ni), platinum (Pt), palladium (Pd), rhodium (Rh), ruthenium (Ru), zinc (Zn), silver (Ag), titanium (Ti), cobalt (Co), molybdenum (Mo), tungsten (W), aluminum (Al), iron (Fe), vanadium (V), iridium (Ir), antimony (Sb), tin (Sn), bismuth (Bi), Manganese (Mn), copper (Cu), barium (Ba), and gold (Au).

17. The manufacturing method of a photodiode according to claim 11, wherein in order to manufacture a photodiode having a schottky junction characteristic between a high conductive electrode and an antireflection semiconductor substrate, a metal contact layer is further formed in an area other than a low reflective and high conductive surface.

18. A solar cell, comprising:
a housing which protects internal elements of the solar cell from the outside; and
a photodiode including a semiconductor substrate which includes a selectively etched electrode formation area and a light absorption area which protrudes relatively from the electrode formation area and an electrode which includes a metal catalyst layer fixed on the electrode formation area of the semiconductor substrate by chemically etching the semiconductor substrate and has an electrical conductivity.

19. The solar cell according to claim 18, wherein the chemical etching is a metal-assisted chemical etching and the semiconductor substrate includes a silicon component and at least partially includes a 3D nanograss structure formed by the metal-assisted chemical etching, a position of the light absorption area is formed at a position corresponding to a position of pinholes which are randomly distributed on the metal catalyst layer by the metal-assisted chemical etching, and the electrode formation area forms a schottky junction or a PN junction with a remaining area of the metal catalyst layer in which pinholes are not provided.

20. The solar cell according to claim 18, wherein the metal catalyst layer at least partially has a metal mesh structure and a surface sheet resistance (SSR) of the metal catalyst is 2≤SSR≤10Ω/□, and a solar weighted reflectance (SWR) and the surface sheet resistance of the metal catalyst layer satisfy 4≤SRR×SWR≤30 (%·Ω/□).
